(19) United States
(12) Patent Application Publication
(10) Pub. No.: US 2015/0001628 A1
(43) Pub. Date: Jan. 1, 2015

(54) SEMICONDUCTOR STRUCTURE WITH IMPROVED ISOLATION AND METHOD OF FABRICATION TO ENABLE FINE PITCH TRANSISTOR ARRAYS

(71) Applicant: GLOBAL FOUNDRIES Inc., Grand Cayman (KY)

(72) Inventors: Nicholas V. LiCausi, Watervliet, NY (US); Daniel Pham, Clifton Park, NY (US); Andy Chi-Hung Wei, Queensbury, NY (US); Zhenyu Hu, Clifton Park, NY (US)

(21) Appl. No.: 13/928,947

(22) Filed: Jun. 27, 2013

(51) Int. Cl. H01L 27/088; H01L 21/762

(52) U.S. Cl. CPC H01L 27/088; H01L 21/76224
USPC 257/368; 438/424

(57) ABSTRACT

An improved structure and method for forming isolation between two adjacent field effect transistors is disclosed. A large substrate cavity is formed between gates of the two adjacent transistors. The substrate cavity is filled with an epitaxial material such as epitaxial silicon, silicon germanium, or III-V compound semiconductor to form an epitaxial region. A cavity is then formed in the epitaxial material, dividing the epitaxial region into two epitaxial regions that serve as source-drain regions.

### FIELD OF THE INVENTION

The present invention relates generally to semiconductor fabrication, and more particularly to a structure with improved device isolation and method of fabrication.

### BACKGROUND

In modern semiconductor device applications, numerous devices are packed onto a single small area of a semiconductor substrate to create an integrated circuit. For the circuit to function, many of these individual devices may need to be electrically isolated from one another. Accordingly, electrical isolation is an important and integral part of semiconductor device design for preventing the unwanted electrical coupling between adjacent components and devices.

As the size of integrated circuits is reduced, the devices that make up the circuits must be positioned closer together in order to comply with the limited space available on a typical semiconductor substrate. As the industry strives towards a greater density of active components per unit area of semiconductor substrate, effective isolation between circuits becomes increasingly important.

### SUMMARY OF THE INVENTION

In a first aspect, embodiments of the present invention provide a method of forming a semiconductor structure, comprising: forming a first gate and a second gate on a semiconductor substrate; forming a substrate cavity disposed between the first gate and the second gate; filling the substrate cavity with an epitaxially grown semiconductor material to form an epitaxial region; forming an epitaxial region isolation trench in the epitaxial region; and filling the epitaxial region isolation trench with an insulator.

In a second aspect, embodiments of the present invention provide a method of forming a semiconductor structure, comprising: forming a first gate and a second gate on a semiconductor substrate; forming a substrate cavity disposed between the first gate and the second gate, wherein the substrate cavity is wider than the first gate; filling the substrate cavity with an epitaxially grown semiconductor material to form an epitaxial region; forming an epitaxial region isolation trench in the epitaxial region; and filling the epitaxial region isolation trench with an insulator.

In a third aspect, embodiments of the present invention provide a semiconductor structure comprising: a semiconductor substrate; a first gate formed on the semiconductor substrate; a second gate formed on the semiconductor substrate; a first epitaxial source-drain region embedded in the semiconductor substrate; a second epitaxial source-drain region embedded in the semiconductor substrate; an insulator region disposed in between the first epitaxial source-drain region and the second epitaxial source-drain region, wherein the insulator region is in direct physical contact with sidewalls of the first epitaxial source-drain region and the second epitaxial source-drain region.

### BRIEF DESCRIPTION OF THE DRAWINGS

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity. Furthermore, for clarity, some reference numbers may be omitted in certain drawings.

Features of this invention will be more readily understood from the following detailed description of the various aspects of the invention taken in conjunction with the accompanying drawings in which:

FIG. 1 is a semiconductor structure at a starting point for illustrative embodiments;

FIG. 2 is a semiconductor structure after a subsequent step of performing a substrate etch, in accordance with illustrative embodiments;

FIG. 3 is a semiconductor structure after a subsequent step of performing a sigma cavity etch, in accordance with alternative illustrative embodiments;

FIG. 4 is a semiconductor structure after a subsequent step of filling the substrate cavity, in accordance with illustrative embodiments;

FIG. 5 is a semiconductor structure after a subsequent step of forming a mask, in accordance with illustrative embodiments;

FIG. 6 is a semiconductor structure after subsequent steps of forming an epitaxial region isolation trench and removing the mask, in accordance with illustrative embodiments;

FIG. 7 is a semiconductor structure after a subsequent step of depositing an insulator layer on the structure, in accordance with illustrative embodiments;

FIG. 8 is a semiconductor structure after a subsequent step of planarizing the insulator layer on the structure, in accordance with illustrative embodiments; and

FIG. 9 is a flowchart indicating process steps in accordance with illustrative embodiments.

### DETAILED DESCRIPTION

Exemplary embodiments will now be described more fully herein with reference to the accompanying drawings, in which exemplary embodiments are shown. Embodiments of the present invention provide an improved structure and method for forming isolation between two adjacent field effect transistors. A large substrate cavity is formed between gates of the two adjacent transistors. The substrate cavity is filled with an epitaxial material such as epitaxial silicon, silicon germanium, or III-V compound semiconductor to form an epitaxial region. A cavity is then formed in the epitaxial material, dividing the epitaxial region into two epitaxial regions that serve as source-drain regions. In this way, proper epitaxial growth is achieved, and the width of the isolation region between the two transistors is a controllable parameter that is not tightly coupled to the width of the gate, providing improved device performance and design flexibility.

It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure (e.g., a first layer), is present on a second element, such as a second structure (e.g. a second layer), wherein intervening elements, such as an interface structure (e.g. interface layer), may be present between the first element and the second element.

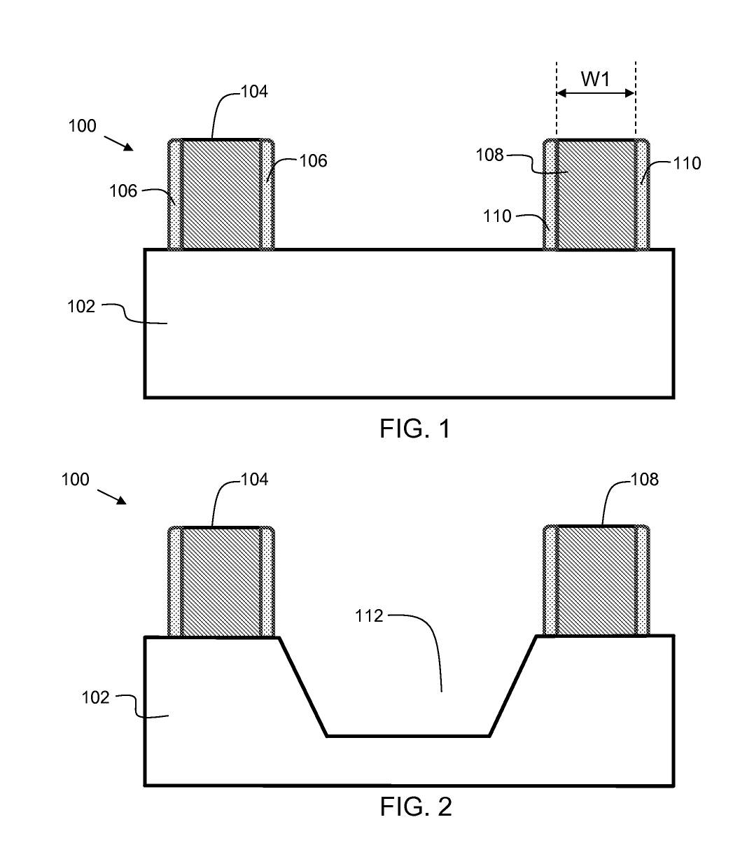

FIG. 1 is a semiconductor structure 100 at a starting point for illustrative embodiments. Semiconductor structure 100 comprises a semiconductor substrate 102, which may be comprised of silicon, or other suitable semiconductor material. Disposed on substrate 102 is a gate 104 and a gate 108. Gate 104 may have spacers 106 adjacent to the gate 104. Gate 108 may have spacers 110 adjacent to the gate 108. The gates 104 and 108 may be comprised of polysilicon. The spacers 106 and 110 may be comprised of nitride, or multiple layers of oxide and nitride, or various oxide/oxide composites. A thin gate dielectric layer (not shown) may be disposed between the gates (104, 108) and the substrate 102. The gates 104 and 108 have a width W1. In some embodiments, width W1 may range from about 15 nanometers to about 150 nanometers. Gates 104 and 108 are each part of a different field effect transistor (FET). In some embodiments, gate 104 and gate 108 are each part of a finFET. In other embodiments, gate 104 and gate 108 are part of a planar FET. The FETs associated with gate 104 and gate 108 may not be electrically connected to each other, or they may be electrically connected to each other through additional metallization layers. In either case, it is desired to provide isolation between the neighboring FET devices, to minimize the unwanted leakage currents that may form between them.

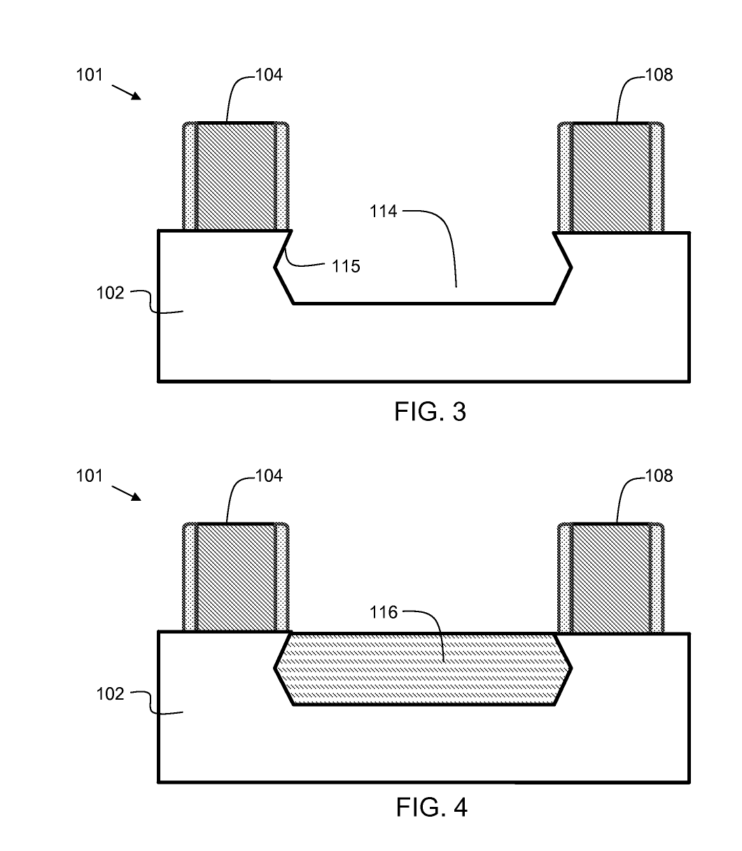

FIG. 2 shows semiconductor structure 100 after a subsequent step of performing a substrate etch, in accordance with illustrative embodiments. A mask (such as photoresist or a hard mask) may be formed and patterned using industry standard lithographic methods. A substrate cavity 112 is then formed in the substrate 102 which is filled with an epitaxial material in a subsequent step. The substrate cavity 112 is disposed between gate 104 and gate 108, and extends partway into substrate 102. In embodiments, the cavity 112 may be formed by an isotropic, or anisotropic etch process. In some embodiments, a reactive ion etch process may be used. In other embodiments, a wet etch process may be used.

FIG. 3 is a semiconductor structure 101 after a subsequent step of forming a sigma cavity 114, in accordance with alternative illustrative embodiments. Sigma cavities are formed using an etch process that is plane sensitive, to create the shape of substrate cavity 114, which includes inclined sidewalls 115 that border the substrate cavity 114, where the sidewalls 115 may substantially correspond to specific crystal planes.

FIG. 4 shows a semiconductor structure 101 after subsequent steps of filling the substrate cavity with an epitaxially grown semiconductor material to form epitaxial region 116, in accordance with illustrative embodiments. The epitaxial region 116 may be formed by growing epitaxial material, and may optionally include a recess to make epitaxial region 116 substantially flush with the top of substrate 102. In embodiments, the epitaxial material that forms epitaxial region 116 may be comprised of silicon, silicon germanium (SiGe), III-V compound semiconductor, or other suitable material. The epitaxial region 116 may be in-situ doped, or may be doped after formation. In the case of post-formation doping, a technique such as ion implantation or plasma doping may be used. The choice of dopants depends on a variety of factors, including whether the FETs are intended as N type FETs (NFETs) or P type FETs (PFETs). Dopants may include, but are not limited to, arsenic, phosphorous, and boron.

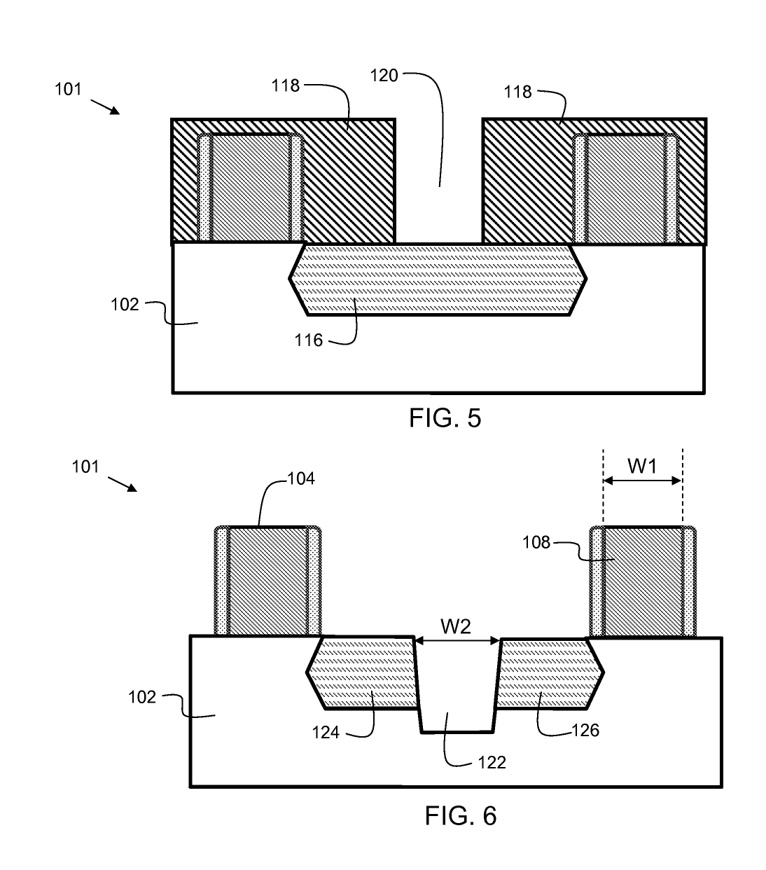

FIG. 5 shows semiconductor structure 101 after a subsequent step of forming a mask 118, in accordance with illustrative embodiments, consistent with conventional industrial lithography practices. Mask 118 has an opened space 120 to expose a portion of epitaxial region 116. Mask 118 may be comprised of photoresist. In some embodiments, a hard mask such as oxide may be used instead of, or in addition to photoresist.

FIG. 6 shows semiconductor structure 101 after subsequent steps of forming an epitaxial region isolation trench 122 and removing the mask (compare with 118 of FIG. 5), in accordance with illustrative embodiments. The epitaxial region isolation trench 122 traverses the epitaxial region and extends partially into substrate 102. The epitaxial region isolation trench 122, at its widest point, has a width W2. In some embodiments, width W2 may be greater than gate width W1. In some embodiments, width W2 may range from about 25 nanometers to about 60 nanometers. The epitaxial region isolation trench 122 may be formed with an anisotropic etch process. In some embodiments, a reactive ion etch process may be used to form epitaxial region isolation trench 122. As the result of the formation of the epitaxial region isolation trench 122, the epitaxial region 116 (see FIG. 5) is now split into two epitaxial regions 124 and 126. Epitaxial region 124 serves as a source-drain region for gate 104, and epitaxial region 126 serves as a source-drain region for gate 108. The term source-drain region implies that the region may serve as either the source, or the drain for a transistor. In embodiments, both epitaxial regions 124 and 126 may be sources or drains. In some embodiments, epitaxial region 124 and epitaxial region 126 may be of different types. For example, epitaxial region 124 may be a source, and epitaxial region 126 may be a drain. The width W2 of the epitaxial region isolation trench 122 is a recipe parameter that may be adjusted by controlling the mask pattern shown in FIG. 5.

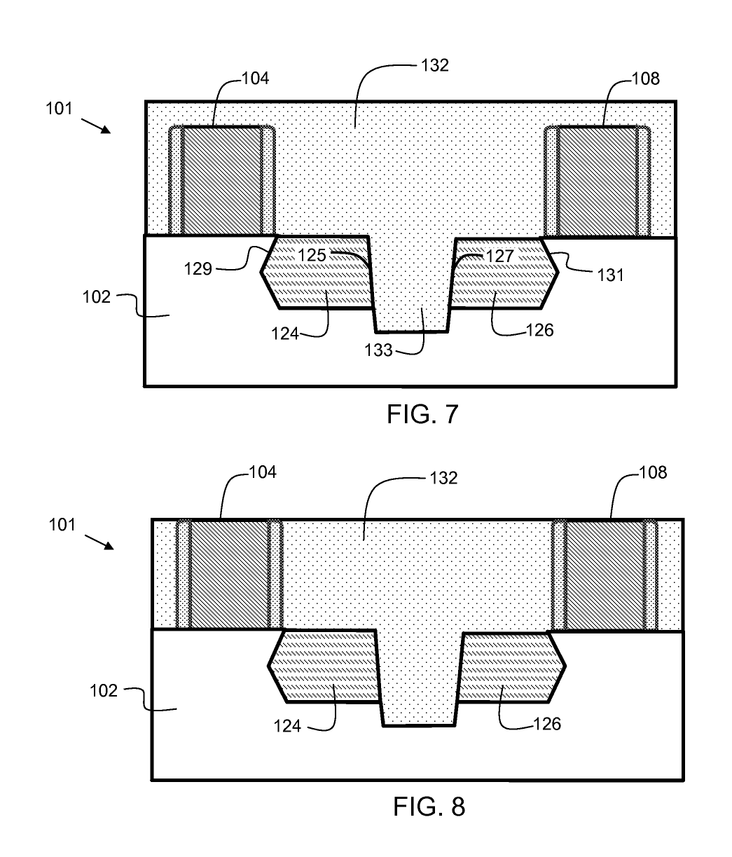

FIG. 7 shows semiconductor structure 101 after a subsequent step of depositing an insulator layer 132 on the structure, in accordance with illustrative embodiments. The insulator layer 132 may be an oxide layer, and may be deposited by chemical vapor deposition (CVD), flowable chemical vapor deposition (FCVD), physical vapor deposition (PVD), or other suitable technique. In some embodiments, insulator layer 132 may be a HARP (high aspect ratio process) oxide, flowable oxide, or other suitable oxide. Insulator region 133 is in direct physical contact with the interior sidewalls (125 and 127) of epitaxial regions 124 and 126, respectively. The exterior sidewalls 129 and 131 of epitaxial regions 124 and 126, respectively, may be of a sigma cavity shape, whereas the interior sidewalls (125 and 127) may be of a planar shape. Hence, the first epitaxial source-drain region 124 and the second epitaxial source-drain region 126 may each have a sigma cavity side and a planar side. Epitaxial regions 124 and 126 may also be stress-inducing regions, providing stress or strain for improving carrier mobility. To complete the transistors, a similar stressor source-drain region (not shown) is formed on the other side of the gate.

FIG. 8 shows semiconductor structure 101 after a subsequent step of planarizing the insulator layer 132 on the structure, in accordance with illustrative embodiments. As a result of the planarization, the top of insulator layer 132 is substantially flush with the top of gates 104 and 108. In embodiments, the planarization may be performed by a chemical mechanical polish (CMP) process or a reactive ion etch (RIE) process.

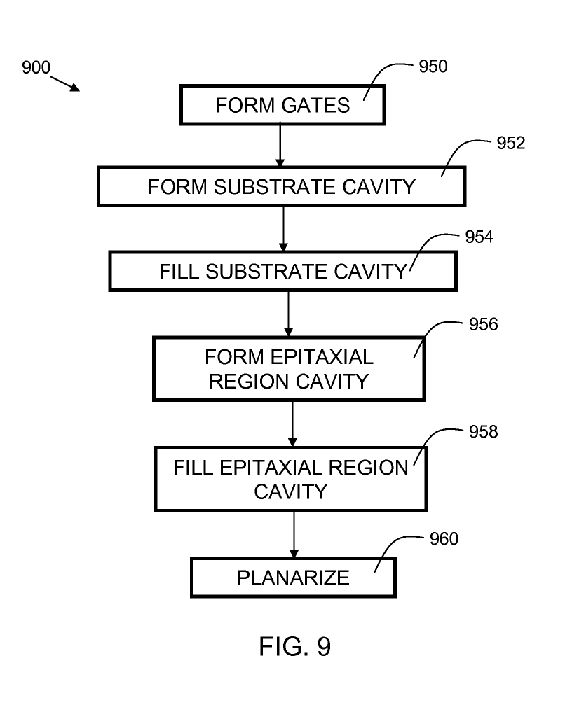

FIG. 9 is a flowchart 900 indicating process steps in accordance with illustrative embodiments. In process step 950, prior transistor definition is conducted finishing with the formation of gates (see 104 and 108 of FIG. 1). In process step 952, the substrate cavity is formed (see 112 of FIGS. 2 and 114 of FIG. 3). In process step 954, the substrate cavity is filled with an epitaxial material (see 116 of FIG. 4). In process step 956, an epitaxial region isolation trench is formed (see 122 of FIG. 6). In process step 958, the epitaxial region isolation trench is filled with an insulator (see 133 of FIG. 7). In process step 960, the structure is planarized. From this point forward, industry standard techniques can be used to complete the integrated circuit. This may include a replacement metal gate (RMG) process, silicidation, contact formation, additional dielectric layers, metallization layers, and packaging.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

1. A method of forming a semiconductor structure, comprising:
forming a first gate and a second gate on a semiconductor substrate;
forming a substrate cavity disposed between the first gate and the second gate;
filling the substrate cavity with an epitaxially grown semiconductor material to form an epitaxial region;
forming an epitaxial region isolation trench in the epitaxial region; and
filling the epitaxial region isolation trench with an insulator.

2. The method of claim 1, wherein forming a substrate cavity comprises performing a wet etch.

3. The method of claim 1, wherein forming a substrate cavity comprises performing a reactive ion etch.

4. The method of claim 1, wherein forming a substrate cavity comprises forming a sigma cavity.

5. The method of claim 1, wherein forming an epitaxial region isolation trench comprises performing a reactive ion etch.

6. The method of claim 1, wherein filling the epitaxial region isolation trench with an insulator comprises depositing an oxide layer to a level above the first gate, and further comprising planarizing the oxide layer to the level of the top of the first gate.

7. The method of claim 6, wherein planarizing the oxide layer comprises performing a chemical mechanical polish.

8. The method of claim 1, wherein filling the substrate cavity with an epitaxially grown semiconductor material to form an epitaxial region comprises filling the substrate cavity with epitaxially grown silicon.

9. The method of claim 1, wherein filling the substrate cavity with an epitaxially grown semiconductor material to form an epitaxial region comprises filling the substrate cavity with epitaxially grown silicon germanium.

10. The method of claim 1, wherein filling the substrate cavity with an epitaxially grown semiconductor material to form an epitaxial region comprises filling the substrate cavity with an epitaxially grown III-V compound semiconductor material.

11. The method of claim 1, further comprising performing in-situ doping during formation of the epitaxial region.

12. The method of claim 1, further comprising performing ion implantation after formation of the epitaxial region.

13. A method of forming a semiconductor structure, comprising:
forming a first gate and a second gate on a semiconductor substrate;
forming a substrate cavity disposed between the first gate and the second gate, wherein the substrate cavity is wider than the first gate;
filling the substrate cavity with an epitaxially grown semiconductor material to form an epitaxial region;
forming an epitaxial region isolation trench in the epitaxial region; and
filling the epitaxial region isolation trench with an insulator.

14. The method of claim 13, wherein forming a substrate cavity comprises forming a sigma cavity.

15. The method of claim 13, wherein filling the substrate cavity with an epitaxially grown semiconductor material to form an epitaxial region comprises filling the substrate cavity with epitaxially grown silicon.

16. The method of claim 13, wherein filling the substrate cavity with an epitaxially grown semiconductor material to form an epitaxial region comprises filling the substrate cavity with epitaxially grown silicon germanium.

17. The method of claim 13, wherein filling the substrate cavity with an epitaxially grown semiconductor material to form an epitaxial region comprises filling the substrate cavity with an epitaxially grown III-V compound semiconductor material.

18. A semiconductor structure comprising:
a semiconductor substrate;
a first gate formed on the semiconductor substrate;
a second gate formed on the semiconductor substrate;
a first epitaxial source-drain region embedded in the semiconductor substrate;
a second epitaxial source-drain region embedded in the semiconductor substrate;
an insulator region disposed in between the first epitaxial source-drain region and the second epitaxial source-drain region, wherein the insulator region is in direct physical contact with sidewalls of the first epitaxial source-drain region and the second epitaxial source-drain region.

19. The semiconductor structure of claim 18, wherein the insulator region has a width greater than the width of the first gate.

20. The semiconductor structure of claim 18, wherein the first epitaxial source-drain region and the second epitaxial source-drain region each have a sigma cavity side and a planar side.
